(19) United States
(12) Patent Application Publication
(10) Pub. No.: US 2009/0050999 A1
(43) Pub. Date: Feb. 26, 2009

(54) Apparatus for storing electrical energy

(75) Inventors: James Chyi Lai, Saint Paul, MN (US); Tom Allen Agan, Saint Paul, MN (US)

Correspondence Address: MUNCY, GEISSLER, OLDS & LOWE, PLLC, Ste 213, 10560 Main St., Fairfax, VA, 22030, US

(73) Assignee: Western Lights Semiconductor Corp.

(21) Appl. No.: 11/892,242

(22) Filed: Aug. 21, 2007

(51) Int. Cl. H01L 29/47

(52) U.S. Cl. 257/471; 257/E29.148

(57) ABSTRACT

An apparatus to store electrical energy is provided. The apparatus includes a first magnetic section, a second magnetic section, and a semiconductor section configured between the first magnetic section and the second magnetic section, wherein the junction between the semiconductor section and the first and second magnetic section forms a diode barrier preventing current flow to store electrical energy.

### BACKGROUND

1. Field of Invention

The present invention relates to an apparatus for storing electrical energy. More particularly, the present invention relates to a magnetic device to store electrical energy.

2. Description of Related Art

Energy storage parts are very important in our life. Components such as capacitors used in the circuits and batteries used in portable devices, the electrical energy storage parts influence the performance and the working time of the electrical device.

However, traditional energy storage parts have some problems. For example, capacitors have a problem of current leakage decreasing overall performance. Batteries have the memory problem of being partially charged/discharged and decreasing overall performance.

The Giant Magnetoresistance Effect (GMR) is a quantum mechanical effect observed in structures with alternating thin magnetic and thin nonmagnetic sections. The GMR effect shows a significant change in electrical resistance from the zero-field high resistance state to the high-field low resistance state according to an applied external field.

Therefore, the GMR effect can be used to be the insulator with good performance. Thus, the apparatus with the GMR effect can be implemented to store electrical energy. However, with the device size continuing to shrink, more capacitance is needed to be stored in limited area.

For the foregoing reasons, there is a need to have an apparatus with the GMR effect to store electrical energy and having large capacitance values.

### SUMMARY

It is therefore an objective of the present invention to provide an apparatus to store electrical energy.

According to one embodiment of the present invention, the apparatus includes a first magnetic section, a second magnetic section, and a semiconductor section configured between the first magnetic section and the second magnetic section, wherein the junction between the semiconductor section and the first and second magnetic section forms a diode barrier preventing current flow from the first magnetic section to the second magnetic section as to store electrical energy.

According to another embodiment of the present invention, the apparatus includes a plurality of magnetic sections, and a plurality of semiconductor sections configured between the magnetic sections alternatively, wherein the junction between each of the semiconductor sections and the magnetic sections forms a diode barrier preventing current flow between the magnetic sections as to store electrical energy.

The diode barrier acts as a dielectric material with a very large dielectric constant. The dielectric constant of the diode barrier may be 5 to 9 orders of magnitudes higher than normal dielectric material. Since the capacitance is directly proportional to the dielectric constant, an increase in the dielectric constant indicates an increase in the capacitance in the energy storing apparatus.

Moreover, the embodiments of the present invention also may increase the capacitance by reducing the thickness of the semiconductor section. Since the distance between the first and second magnetic sections also affects the capacitance, reducing the thickness of the semiconductor section may increase the capacitance of the apparatus.

Lastly, since the capacitance is also proportional to the junction area, by having a junction with a rough surface can increase the surface area of the junction and thus leads to larger capacitance.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 shows an apparatus to store electrical energy according to an first embodiment of the invention;

FIG. 1A shows a circuit symble for the junction between the semiconductor section and the first and second magnetic section forming a diode barrier; and

FIG. 2 shows the apparatus to store electrical energy according to a second embodiment of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

All figures are drawn for ease of explanation of the basic teachings of the present invention only; the extensions of the figures with respect to number, position, relationship, and dimensions of the parts to form the embodiment will be explained or will be within the skill of the art after the following description has been read and understood.

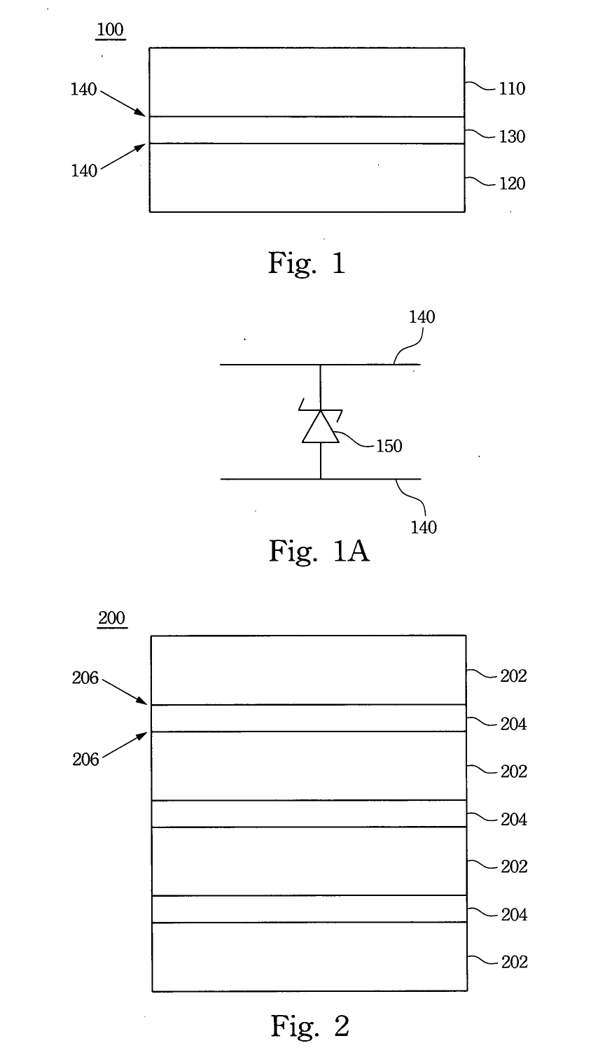

Please refer to FIG. 1, an apparatus to store electrical energy according to a first embodiment of the present invention. The apparatus 100 to store electrical energy includes a first magnetic section 110, a second magnetic section 120, and a semiconductor section 130 configured between the first magnetic section 110 and the second magnetic section 120. The first magnetic section 110, the second magnetic section 120, and the semiconductor section 130 may be thin films. The semiconductor section 130 may be made of a semiconductor material. The junction 140 between the semiconductor section 130 and the first and second magnetic section forms a diode barrier 150 as shown in FIG. 1A, a circuit diagram of the apparatus 100 to preventing current flowing from the first magnetic section 110 to the second magnetic section 120, thus storing electrical energy therein.

The diode barrier formed may be a Schottky diode barrier 150 with rectifying characteristics so that when a small voltage is applied across the Schottky diode barrier 150, the diode barrier 150 remains at the “off” state which prevents current from flowing between the magnetic sections 110, 120. The small voltage is less than the turn-on voltage of the diode barrier 150. Due to the current prevention characteristics of the diode barrier 150, the semiconductor section 130 acts as a dielectric material. The dielectric characteristics of the diode barrier 150 may be further improved by applying a magnetic field to the semiconductor section 130. The magnetic field may be provided by the first and second magnetic sections 110, 120. The magnetic field acts as a force to prevent escaping charges from the semiconductor section 130. Therefore, the magnetic field provides additional dielectric performance to the diode barrier 150. The dielectric performance of a material is represented by the dielectric constant of the material, which in a relationship with the capacitance is:

$$C = \frac{{ɛ}_{o} {ɛ}_{k} A}{r} \qquad ( 1 )$$

where C is the capacitance of a energy-storing apparatus, ∈ₒ is a constant (approximately 8.85e-12), ∈ₖ is the dielectric constant of the material between the first and second magnetic sections 110 and 120, A is the surface area of the junction, and r is the distance between the first and second magnetic sections 110 and 120. From the equation (1), if the dielectric constant of the material between the first and second magnetic sections 110 and 120 increases, the capacitance will increase. Thus, with the strong dielectric performance of the diode barrier and the magnetic field, the dielectric constant of the semiconductor section 130 is much larger than normal dielectric materials. The dielectric constant of the semiconductor section 130 may be 5 to 9 orders of magnitude larger than normal dielectric materials.

In order to increase the capacitance of the apparatus 100 further, two more structural alternations may be implemented. First, from equation (1), if the distance between the first and second magnetic sections 110 and 120 is reduced, the capacitance can increase. Therefore, when the thickness of the thin film semiconductor section 130 is reduced, the capacitance of the apparatus 110 may be further increased. For example, by reducing the thickness of the semiconductor section 130 to less than 30 angstroms, the capacitance may be significantly reduced compared to if the thickness of the semiconductor section 130 in millimeter range in typical capacitors. When the thickness is reduced to less than 30 angstroms, the method for determining the change in capacitance is defined by the Taylor expansion series, which defines subsequent order terms. Second and possibly third order terms may be significant to lower the breakdown voltage of the apparatus 100. Therefore, consider reducing the thickness of the semiconductor section 130 as a trade-off between capacitance and breakdown voltage.

Second, since the capacitance is directly proportional to A in equation (1), the surface area of the junction 140 may be increased by having an uneven interface between the first and second magnetic sections 110, 120 and the semiconductor section 130. The surface roughness introduces more effective junction area than a flat surface area and thus may increase the capacitance significantly.

According to a second embodiment of the present invention, the apparatus 100 may be stacked to form a multi-layer apparatus 200 for storing electrical energy. Please refer to FIG. 2, the apparatus 200 includes a plurality of magnetic sections 202 and a plurality of semiconductor sections 204. The semiconductor sections 204 are configured between the magnetic sections 202, alternatively, so that the capacitances provided by each of the junctions 206 may be connected in parallel to produce a larger capacitance. Similar to the first embodiment of the present invention the junction 206 between each of the semiconductor sections are the magnetic sections forms a diode barrier preventing current flow between the magnetic sections, so that electrical energy is stored by the apparatus 200.

The embodiment of the present invention is an apparatus for storing electrical energy. The apparatus has more capacity than a standard capacitor. Also, the apparatus can be utilized as batteries in many applications with a faster charge and discharge time than regular batteries. The apparatus does not share the memory restrictions as with batteries, in that the apparatus can be fully or partially discharged between each recharge without loss of performance thus has a much higher number of recharges compared to regular batteries. Lastly, since the apparatus is made of magnetic devices, heating problems present with batteries will not be an issue for the embodiments of the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus to store electrical energy, comprising:
a first magnetic section;
a second magnetic section; and
a semiconductor section configured between the first magnetic section and the second magnetic section;
wherein the junction between the semiconductor section and the first and second magnetic section forms a diode barrier preventing current flow from the first magnetic section to the second magnetic section as to store electrical energy.

2. The apparatus of claim 1, wherein the semiconductor section is a thin film.

3. The apparatus of claim 2, wherein the thin film has a thickness of less than 30 angstroms.

4. The apparatus of claim 1, wherein the semiconductor section is composed of semiconductor material.

5. The apparatus of claim 1, wherein the first magnetic section is a thin film.

6. The apparatus of claim 1, wherein the second magnetic section is a thin film.

7. The apparatus of claim 1, wherein the junction has an uneven interface.

8. The apparatus of claim 1, wherein the diode barrier experiences a voltage across of less than a turn-on voltage.

9. The apparatus of claim 1, wherein the electrical energy is stored in the diode barrier when magnetic field is applied thereto.

10. The apparatus of claim 1, wherein the diode barrier is a Schottky diode barrier.

11. An apparatus to store electrical energy, comprising:
a plurality of magnetic sections; and
a plurality of semiconductor sections configured between the magnetic sections alternatively;
wherein the junction between each of the semiconductor sections and the magnetic sections forms a diode barrier preventing current flow between the magnetic sections as to store electrical energy.

12. The apparatus of claim 11, wherein the semiconductor section is a thin film.

13. The apparatus of claim 12, wherein the thin film has a thickness of less than 30 angstroms.

14. The apparatus of claim 11, wherein the semiconductor section is composed of semiconductor material.

15. The apparatus of claim 11, wherein the first magnetic section is a thin film.

16. The apparatus of claim 11, wherein the second magnetic section is a thin film.

17. The apparatus of claim 11, wherein the junction has an uneven interface.

18. The apparatus of claim 11, wherein the diode barrier experiences a voltage across of less than a turn-on voltage.

19. The apparatus of claim 11, wherein the electrical energy is stored in the diode barrier when magnetic field is applied thereto.

20. The apparatus of claim 11, wherein the diode barrier is a Schottky diode barrier.
